(19) United States
(12) Patent Application Publication
(10) Pub. No.: US 2011/0075341 A1
(43) Pub. Date: Mar. 31, 2011

(54) Display Assembly

(75) Inventors: Jack LAU, Hong Kong (HK); Ning DENG, Hong Kong (HK); Kin-Yee Kenny KOO, Hong Kong (HK)

(73) Assignee: PERCEPTION DIGITAL LIMITED, Hong Kong (HK)

(21) Appl. No.: 12/568,262

(22) Filed: Sep. 28, 2009

(51) Int. Cl. G06F 1/16; H05K 7/02

(52) U.S. Cl. 361/679.21; 361/807

(57) ABSTRACT

A display assembly in which multiple display panels for showing different images such as digital photos or moving images can be removably attached to a mounting board in different angles and configuration. The mounting board supplies power to the display panels, easing the logistic handling of cables to the display panels.

### FIELD OF THE INVENTION

This invention relates generally to display panels and more particularly to a configurable assembly of display panels.

### BACKGROUND OF THE INVENTION

It is a present day trend to place multiple display panels, or screens, along side each other to form an assembly showing multiple digital images at once. The multiple images may form a single larger image, or may form a mosaic of different images. Furthermore, any of the images may be a moving one, such as television show, or a static image. It is popular in a domestic setting to use several digital photograph frames of relatively small size to display an array of digital family portraits.

Unfortunately, such arrangements are expensive or difficult to set up and maintain. Partly, the physical arrangement of such display panels is not easy and the display panels are prone to falling over and must be delicately balanced or installed. Furthermore, such display panels each come with a processor for processing the digital images and the total cost for displaying several images can add up to an expensive sum. Furthermore, every display panels requires a separate power supply. Furthermore, such display panels may receive image signals from an external source. Thus, the electric and signal cables impose a limitation on the arrangement of the display panels. Firstly, it is difficult to hide the cables from view. Furthermore, it is also difficult to be creative with the arrangement due to the need to organise the many cables to the different display panels. After the display panels have been arranged, it is troublesome to re-arrange the display panels. Generally, the greater the number of display panels, the more difficult it is to organise the mess of cables and the different software needed to show pictures of different digital format.

In some conventional display assemblies, a large metal rack is provided into which the display panels of the same size is fitted in an orderly arrangement to from a large screen. It is impossible to change the arrangement of the assembly because the metal rack is not made for varying the display panel arrangement.

Therefore it is desirable to provide a way to make the management of the signal and electric cables of a plurality of display panels easier, and to provide a possibility to vary the arrangement of the display panels in order to allow more creative ways to display images.

### SUMMARY OF THE INVENTION

In a first aspect, the invention proposes a display assembly comprising a mounting board, an attachment device on the mounting board, at least one display panel mounted to the attachment device, the mounting board capable of providing power to operate the at least one display panel.

In a second aspect, the invention proposes a mounting board comprising an attachment device, the attachment device for attaching to a display panel; and power connection to operate the display panels.

In the third aspect, the invention proposes a display panel for mounting to an attachment device of a mounting board, wherein the mounting board provides power to operate the display panel.

Preferably, the at least one display panel is removably mounted to the attachment device. Preferably, the at least one display panel is mounted to the attachment device such that the at least one display panel can be moved to change the angle of the at least one display panel to the mounting board. Preferably, the position attachment device on the mounting board is movable.

Advantageously, the invention provides the possibility of having a device with a simple power supply to support one-to-many photograph frames or multiple display panels. Furthermore, the invention provides the possibility of mounting different display panels in different positions on the mounting board, in different angular rotation. Thus, the invention provides the possibility of a variety of creative arrangement of the display panels to show different images.

Preferably, the mounting board is capable of providing power to operate the at least one display panel by induction.

Preferably, the display panels are able to receive data signal wirelessly.

In yet another aspect, the invention proposes a mounting board, two or more display panels mounted to the mounting board; wherein one of the display panels comprises a processor; and the other display panels relying on the processor in the one of the display panels to process image data.

In yet another aspect, the invention proposes a mounting board, wherein the mounting board comprises a data bus for a first display panel attached to the mounting board to access a processor in a second display panel attached to the mounting board, wherein the processor in the second display panel processing image data for the display panel.

In yet another aspect, the invention proposes a display panel for mounting to a mounting board, wherein the display panel relies on a processor in another display panel mounted to the mounting board to process image data.

In yet another aspect, the invention proposes a display panel for mounting to a mounting board, wherein the display panel has a processor for processing image data for another display panel mounted to the mounting board.

Thus, specific embodiments of the invention provide ease of assembly particularly the embodiments which uses wireless data signal connection and wireless display panel. These embodiments possibly improve the convenience of assembling a display assembly due to reduced cablings for power or data signal connection.

### BRIEF DESCRIPTION OF THE FIGURES

It will be convenient to further describe the present invention with respect to the accompanying drawings that illustrate possible embodiments of the invention, in which like reference numbers refer to like parts. Other embodiments of the invention are possible, and consequently the particularity of the accompanying drawings is not to be understood as superseding the generality of the preceding description of the invention.

FIG. 1 illustrates a first embodiment of the invention;

FIG. 2 illustrates a part of the embodiment of FIG. 1;

FIG. 3 illustrates an further part of the embodiment of FIG. 1;

FIG. 4 illustrates a possible arrangement of the part illustrated in FIG. 3;

FIG. 5 illustrates an alternative arrangement of the part illustrated in FIG. 3;

FIG. 5a is another illustration of the further part of the embodiment of FIG. 1;

FIG. 6 illustrates how the embodiment of FIG. 1 is deployed;

FIG. 7 illustrates how the embodiment of FIG. 1 is alternatively deployed;

FIG. 8 illustrates how the embodiment of FIG. 1 is alternatively deployed;

FIG. 9 illustrates the internal architecture of the embodiment of FIG. 1;

FIG. 10 illustrates an alternative internal architecture of the embodiment of FIG. 1;

FIG. 11 illustrates yet another alternative internal architecture of the embodiment of FIG. 1;

FIG. 12 illustrates yet another alternative internal architecture of the embodiment of FIG. 1;

FIG. 13 illustrates yet another alternative internal architecture of the embodiment of FIG. 1;

FIG. 13a illustrates yet another alternative internal architecture of the embodiment of FIG. 1;

FIGS. 14a to 14f illustrate a variation of the embodiment of FIG. 1;

FIG. 15 illustrates another embodiment of the invention;

FIG. 16 illustrates another embodiment of the invention;

FIG. 17 illustrates another embodiment of the invention; and

FIG. 18 how the embodiment of FIG. 17 is used in one possibility.

### DETAILED DESCRIPTION OF THE EMBODIMENTS

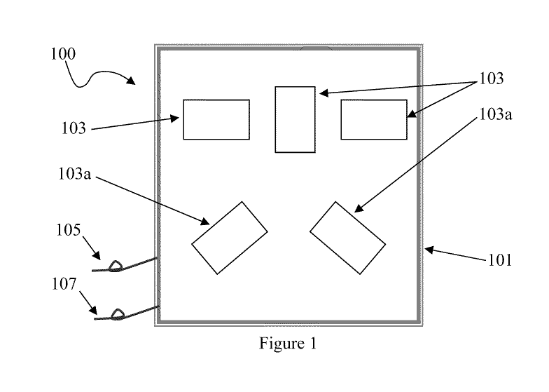

FIG. 1 illustrates an embodiment 100 which is an assembly of a plurality of display panels 103 and a mounting board 101. The display panels 103, 103a are capable of displaying both static and moving images, and can be any type of display monitor, such as an LCD, OLED, a plasma panel and so on. The display panels 103 are mounted to the mounting board 101 in such a way that the position of the display panels 103 relative to the mounting board 101 is variable. For example, the display panels 103a can also be arranged on the mounting board 101 in different rotated positions. Furthermore, the display panels 130 can be removed from one location on the mounting board 101 and placed on another location on the mounting board 101.

Having a plurality of display panels 103 on the mounting board 101 allows images from different data sources to be shown at once. For example, one display panel 103 is showing a moving image, such as a television program, while another display panel 103 is showing a static image, such as a digital photograph.

The mounting board 101 obtains power from a power mains supply 105, and transfers the power to operate the display panels 103. Furthermore, the mounting board 101 is connected to one or more data signal cables 107 to receive data signals for display by the display panels 103.

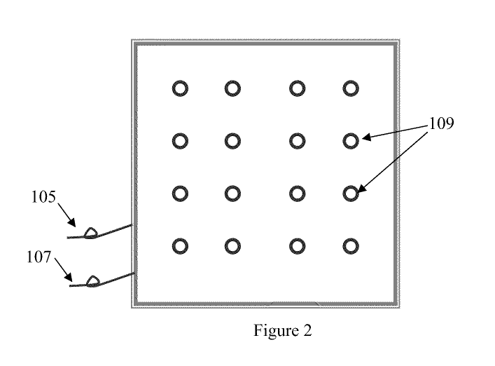

FIG. 2 illustrates the mounting board 101 without the display panels 103 mounted, and reveals a plurality of ‘attachment points’ 109. Each attachment point 109 comprises an attachment device for mounting the display panels 103 to the mounting board 101. The attachment device is, optionally, a hinge, a buckle, a mechanical slot, or an adhesive tape or glue, or any other device or means as the skilled man would know, which cooperates with a corresponding attachment device on the display panels 103.

Preferably, the attachment device allows each panel to be removably mounted such that the user is able to vary the location of the display panels on the mounting board 101, or vary the angle of the display panels to the mounting board 101.

Preferably, the attachment device is a ball and socket snap-on connection, which allows the display panels 103 to be rotated into different angles relatively to the mounting board 101.

The arrangement of the attachment points 109 on the mounting board 101 shown in FIG. 2 is just one possible arrangement, wherein the attachment points 109 are arranged in orderly rows and columns. The position of a display panel 103 on the mounting board 101 is a matter of choice of which attachment point 109 to attach the display panels 103. Thus, it is possible that a different number of display panels 103 can placed in different arrangements on the mounting board.

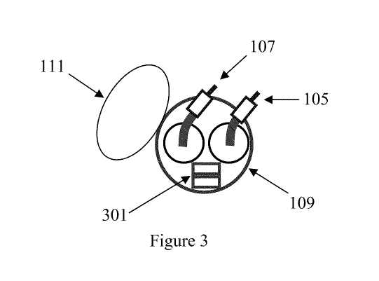

A power cable 105 and a data signal cable 107 are laid inside the mounting board 101 and are available for connecting to the display panels 103 at each attachment point 109. FIG. 3 shows how the power cable 105 and data signal cable 107 as well as the attachment device 301 is available at the attachment point 109. Optionally, the attachment point 109 has a hole that allows the connectors of the electric cable 105 and the data signal cable 107 inside the mounting board 101 to emerge. Furthermore, the attachment device 301 for mounting the display panel 103 is also located in the hole. Thus, a display panel 103 mounted to the attachment point 109 can be connected to the power cable 105 and data signal cable 107 from the same hole. A cover 111 is provided to cover the hole, so that when the power cable 105 and data signal cable 107 are not in use, the hole is covered to look flat and neat and to protect the cables from dust.

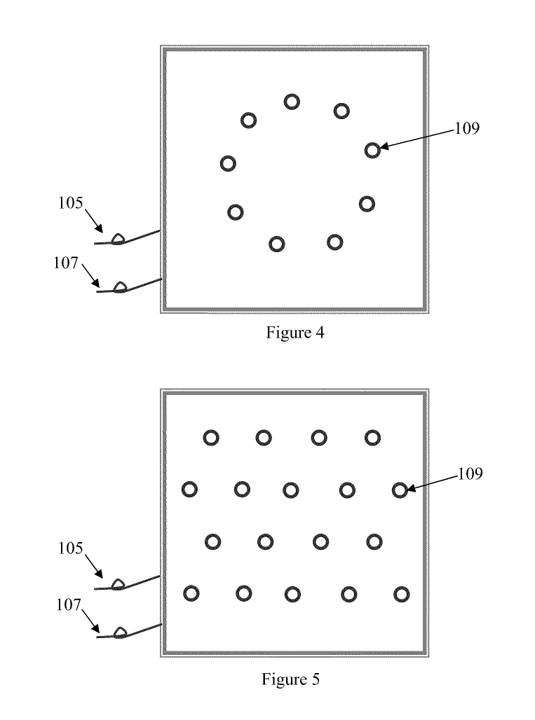

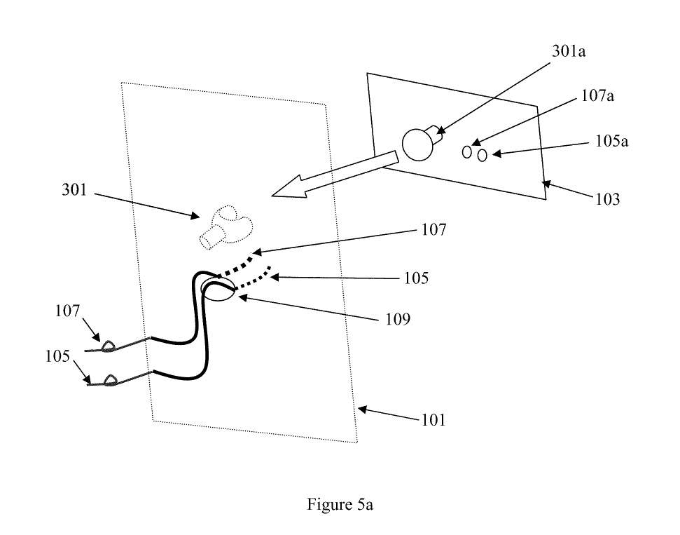

For greater variation, even the location of the attachment points 109 is varied in different versions of the mounting board 101. FIG. 4 illustrates an alternative example in which the attachment points 109 are arranged in ring on the mounting board 101. FIG. 5 illustrates yet another alternative example, in which the attachment points 109 are arranged in staggered neighbouring rows. Compared with the arrangement of the attachment points 109 in FIG. 2, the staggered neighbouring rows of attachment points 109 in the layout of FIG. 5 allows a smaller number of attachment points 109 to cover more area of mounting board 101. Generally, however, the greater the density of attachment points 109 on the mounting board 101, the greater the number of possible variations to the position of display panels 103 on the mounting board 101.

Furthermore, the angle or orientation of display panels 103 can be rotated, so that some of the display panels 103 are slanted while other display panels 103 are oriented upright (see FIG. 1). The extent to which the display panels 103 can be rotated depends on the type of attachment device used at the attachment point 109. The aforementioned ball and socket attachment device allows a display panel 103 to be rotated in three-dimension space, only to be limited when an edge or side of the display panel 103 touches the surface of the mounting board 101.

FIG. 5a is a transparent view of a mounting board from its back, showing a receiving socket, which is an example of an attachment device 301, on the mounting board 101. The receiving socket 301 is able to snap onto a ball device on the back of a display panel 103, which is a corresponding attachment device 301a, to hold the display panel on the mounting board 101 such that the display panel is free to be rotated into different positions about the attachment device 301. FIG. 3a also shows how the electric power cable 105 and the data signal cable 107 is threaded inside the mounting board 101 to emerge at a hole at the attachment point 109, to be connected to corresponding electric power connector 105a and a corresponding data signal connector 107a at the back of the display panel. FIG. 3a only illustrates one attachment device 301 and one attachment point 109, but the skill man understands that there is a plurality of such attachment points 109 and attachment points 109 in some embodiments.

If yet greater degree of movement is desired, it is possible to use an extendible supporting arm, not illustrated, which is pivoted at one end to the mounting board 101 and which pivoted at the other end to a display panel. Other types of attachment device can be used, as the skilled man knows.

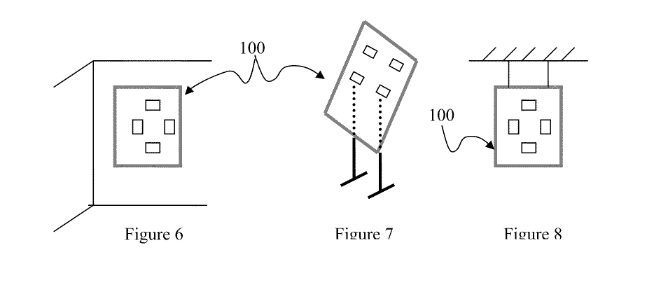

The mounting board 101 can be placed anywhere where there is a suitable source of mains. FIG. 6 shows the mounting board 101 hung onto an indoor wall. FIG. 7 shows the mounting board 101 put onto a prop stand. FIG. 8 shows the mounting board 101 onto an outdoor wall.

Various examples of the hardware architecture of the display assembly 100 will now be described.

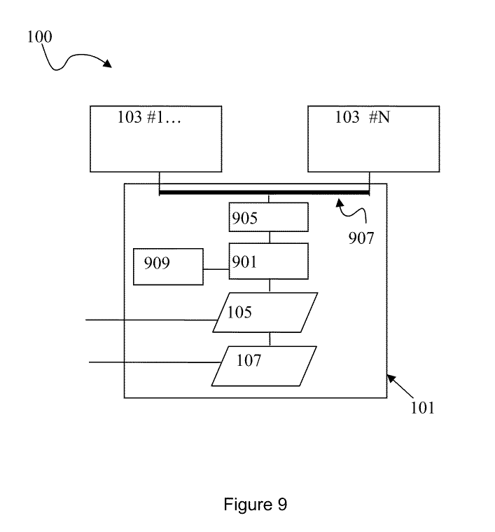

FIG. 9 illustrates a first example in which the mounting board 101 has a processor 901, and a memory 909 such as a RAM, an input and output control unit 905 to process and decode the data signal received by the mounting board 101. The processed data signal data is then fed to the selected display panels via a data bus 907. Advantageously, this example provides the possibility of a single processor 901 used for a plurality of display panels 103, #1 to #N, to show different images.

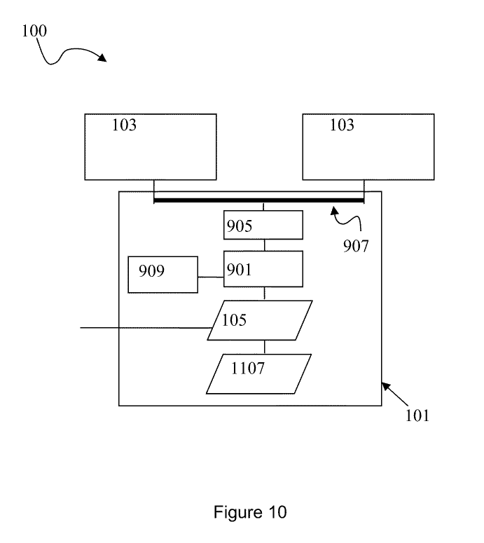

Alternatively, the mounting board 101 does not rely on a data signal cable 107 to receive data signal. Instead, the mounting board 101 contains a non-volatile memory 1107, which stores the images to be displayed. This is illustrated in FIG. 10. The data from the non-volatile memory is processed by the processor and sent via a data bus to whichever of the display panels that is supposed to show the image. How to channel the right stream of image data to the right display panel in a network of hardware is known and need not be discussed here. Thus, the data signal cable 107 shown in FIG. 9 is omitted (as an option) in FIG. 10. The skilled man understands that the non-volatile memory can be an internal flash memory, a hard disk drive, a removable optical disc, a removable compact disc, DVD, or external storage devices such as SD, MMC, USB disk etc.

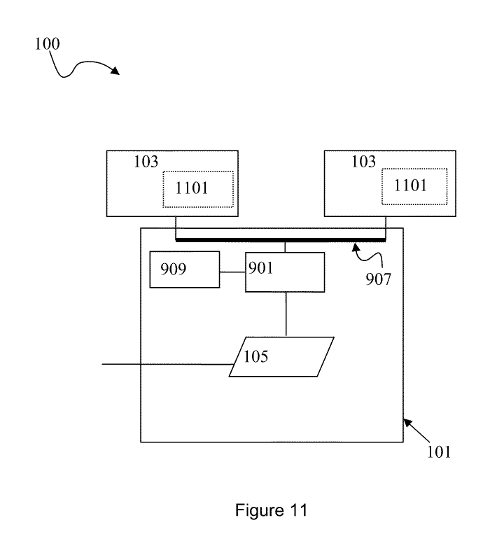

Alternatively, wireless data signal transmission is used to send data of the images to be shown in the display panels 103. FIG. 11 shows that a transceiver 1101 is provided in each display panel 103. Data may be transferred to each display panel via WiFi, Bluetooth, infrared, etc. If necessary, the data bus 907 in the mounting board 101 allows the received data signal to be sent from each display panel 103 to the processor 901 to be processed, and for the processed image to be returned to the appropriate display panel 103. Advantageously, this reduced the amount of wiring within the mounting board 101.

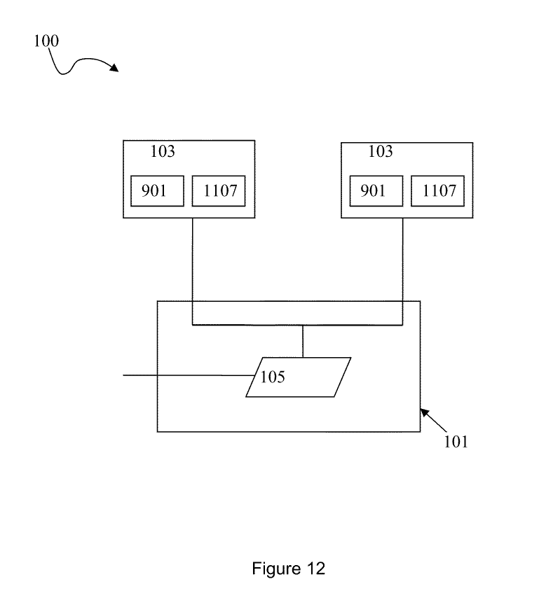

Alternatively, the display panels 103 all operates independently of each other. FIG. 12 shows that each display panel 103 contains a non-volatile memory 1107 which stores image data to be displayed, and a processor 901 for processing the image data. The skilled man understands that the display panels 103 also comprise any other necessary parts for processing the images stored in the non-volatile memory. In this case, the mounting board 101 only provides electric power to the display panels 103. This embodiment incurs the extra cost of a processor and non-volatile memory in each panel. However, the advantage is that, if the processor in any of the display panels breaks down, the operation of the other display panels are not affected since the display panels operate independently.

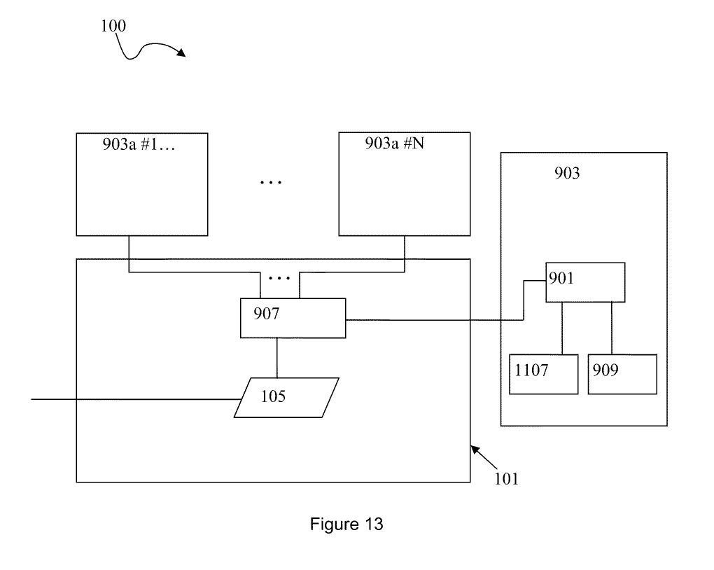

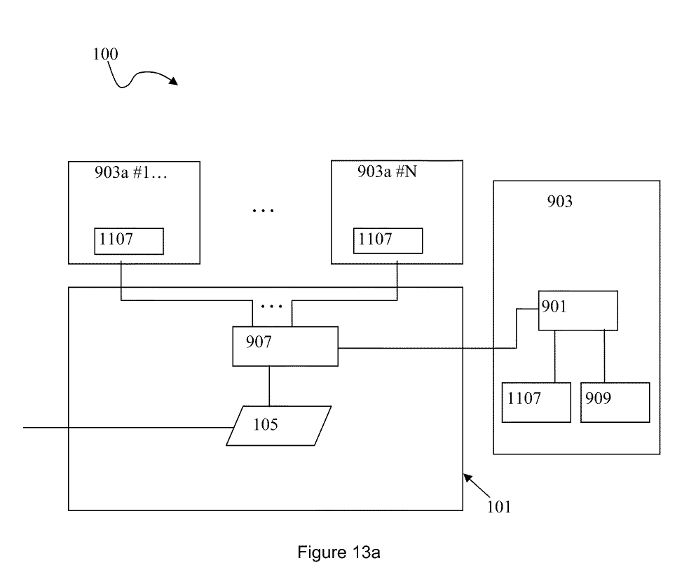

FIG. 13 illustrate another example wherein the display assembly 100 has a ‘master display panel’ 903, which is a display panel is like the other display panels in the display assembly except that the master display panel 903 contains a processor 901 to be shared by all other display panels attached to the mounting board 101. The other display panels, #1 to #N, are known as ‘secondary’ display panels 903a. The master display panel 903 comprises a non-volatile memory storage 1107 for storing image data for all the display panels 903a, and also comprises a processor 901, RAM 909 and other devices necessary to process image data, as would be known to the skilled man (not illustrated). In operation, the master display panel 903 processes images from the image data stored in the non-volatile memory storage 1107 and sends the images to the appropriate display panel 903, 903a for display, including to both the master display panel 903 itself and the secondary display panels 903a.

FIG. 13a shows a variation of this embodiment 100, in which the secondary display panels 903a each has a non-volatile memory 1107 for storing image data. In this case, the image data is sent from the secondary display panels 903a to the master display panel 903 for processing, and then sent back after processing to the appropriate secondary display panel 903. Typically, the secondary display panels 903 access the processor in the master display panels 903 in turns. Advantageously, this example provides the possibility to save costs by using one processor shared among a plurality of display panels and the flexibility of changing the image data in the display panel easily, such as by replacing an image containing DVD inside one of the display panel. In more detail, the processor 901 reads the image data from the non-volatile memory storage 1107 of one of the display panels, processes the data, and then transmits back to the register memory (not illustrated) of the display panel 903 for display. Depending on the processor 901 and the image data, the duration of such processing may be tens of milliseconds to several seconds. The processor 901 then conducts similar processing on the next display panel 903 and loops the processing. Every display panel 903 keeps showing the processed image data in its register memory until the register memory is updated by the next-round processing of the processor 901.

In another variation of the embodiment 100, the display panels 103 are powered by a battery installed in each of the display panels 103, instead of by power cables connected to the display panels 103. In this case, the mounting board 101 does not provide power to the display panels. The batteries in the display panels are then replaced whenever necessary.

In a further variation, the battery is rechargeable and, preferably, can be charged wirelessly. For example, the batteries can be charged by power induction. For example, each display panel 103 contains a power receiving coil to receive power from a transmitting wire coil 509 in the mounting board 101 for charging the battery.

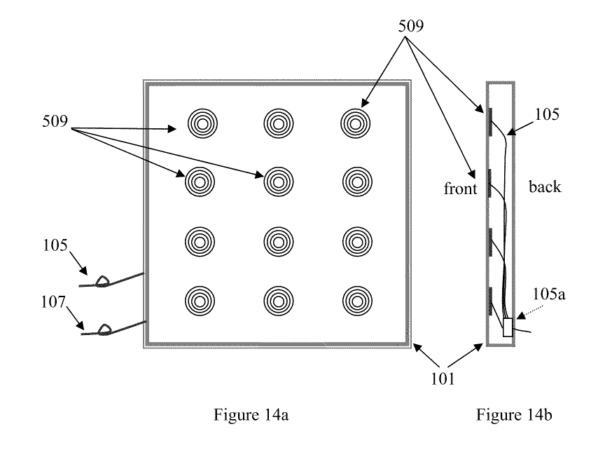

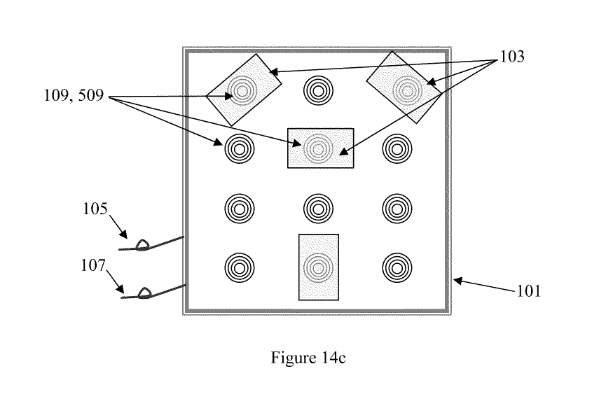

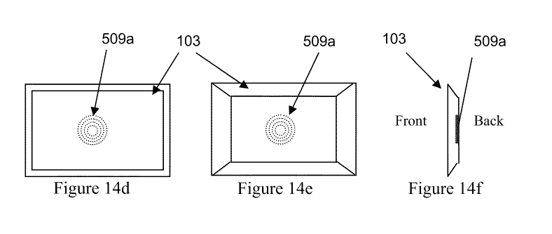

FIG. 14a illustrates a mounting board 10s1 installed with a plurality of power transmitting coils 509. The positions of the power transmitting coils 509 are placed at or near the attachment points 109, but preferably integrated inside the attachment points 109, to coincide with the position of the power receiving coil inside the display panels. This is further illustrated in FIG. 14b, showing the cross-sectional side view of the mounting board 101 of FIG. 14a. FIG. 14c illustrates the corresponding mounting board 101 of FIG. 14a having power transmitting coils 509 overlaid with display panels.

FIG. 14d illustrate the front view of a display panel 103 with a power receiving coil 509a that corresponds to a power transmitting coil 509 in the mounting board 101. FIG. 14e is the corresponding view from the back and FIG. 14f is the corresponding side view.

Preferably, the position of the power transmitting coil 509 in the attachment point 109 is where the electric power cable 107 emerges from the hole, as shown in FIG. 3, as the connector electric power cable 107 can be omitted and replaced by the power transmitting coil 509.

The power receiving wire coil 509a in each display panel 103 and the power transmitting wire coils 509 in the mounting board 101 are tuned to the same electromagnetic frequency to facilitate power transfer. The mounting board 101 is capable of detecting the presence of a power receiving coil 509a, which indicates the presence of a display panel 103 installed on the mounting board 101. For example, when a power receiving coil 509a in a display panel 103 is placed near a power transmitting wire coil 509 in the mounting board 101, the impedance load on the power transmitting wire coil 509 drops. The drop in impedance triggers the power transmitting wire coil 509 to be powered to cause inductive power transfer to the power receiving wire coil 509a in the display panel 103. Hence, each power transmitting wire coil 509 automatically turns ON and OFF depending on whether a display panel 103 is placed on the attachment point 109.

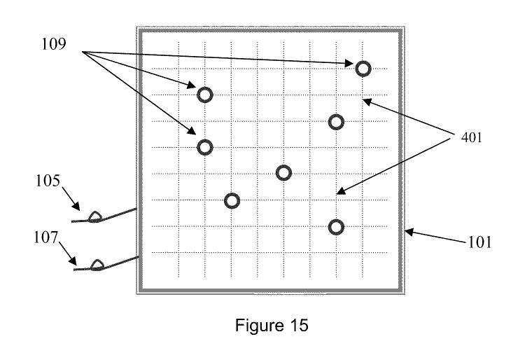

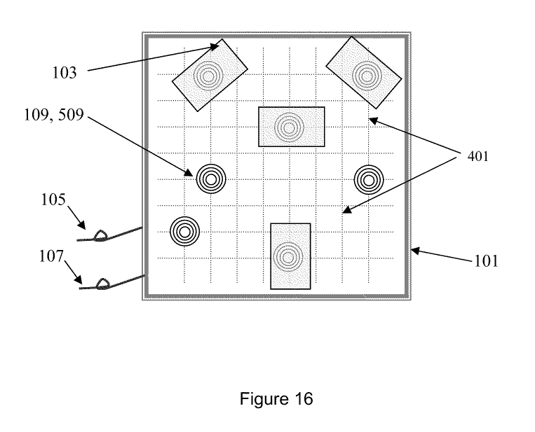

FIG. 15 illustrates another embodiment 100, in which the mounting board 101 comprises a mesh of lengthwise and sidewise railings 401. The attachment points 109 are movably placed on the railings 401. Thus, the user can potentially attach a display panel at any position along the rails. Advantageously, the total number of attachment points 109 on the mounting board 101 can be less than that of the foregoing embodiments 100, but because the attachment devices 301 are movable, the possible arrangements of the display panels 103 on the mounting board may be the same. Advantageously, the number of electric power cables and data signal cable in this example of the mounting board 101 is correspondingly reduced. FIG. 16 illustrates a variation of this embodiment, in which the power transmitting wire coil 509 on the mounting board 101 is movable along with the attachment points 109 on the railings 401

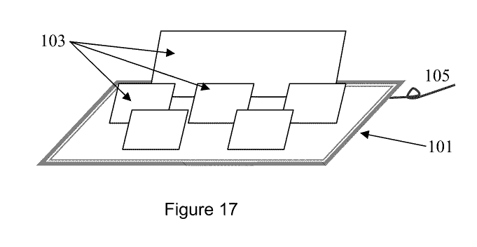

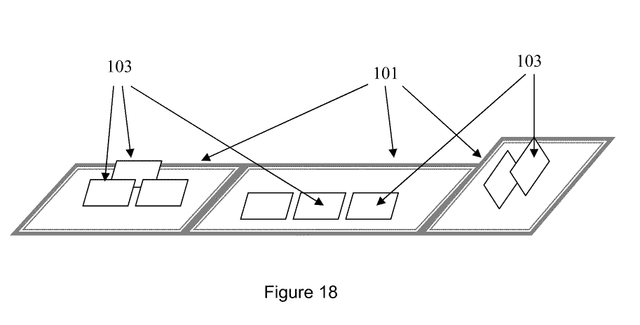

FIG. 17 shows another embodiment 100, in which the display panels 103 are attached to the mounting board 101 by a hinge on one side of the display panel. Thus, the display panels 103 can be lifted away from the mounting board 101 on the hinged end and be propped up. Thus, the mounting board 101 is optionally laid flat on a table and the display panels 103 are secured in a lifted configuration for viewing. This arrangement is useful for displaying an assortment of digital photographs in a domestic setting, as in a mantelpiece display. A variation to this embodiment 100, as shown in FIG. 18, is to place multiple mounting boards 101 alongside each other to form an extended mounting board 101. For example, multiple mounting boards 101 may be simply placed together, or be mechanically hooked up together

Accordingly, the embodiments described are a display assembly 100 comprising, a mounting board 101, an attachment device 301 on the mounting board 101, at least one display panel 103 mounted to the attachment device 301, the mounting board 101 capable of providing power 105 to operate the at least one display panel 103.

Furthermore, the embodiments described have a mounting board 101 comprising an attachment device 301, the attachment device 301 for attaching to a display panel 103 and power connection 105 to operate the display panel 103.

Furthermore, the embodiments 100 described have a display panel 103 for mounting to an attachment device 301 of a mounting board 101, wherein the mounting board 101 provides power 105 to operate the display panel 103.

Furthermore, some embodiments 100 is a display assembly comprising a mounting board, two or more display panels mounted to the mounting board; wherein one of the display panels comprises a processor; and the other display panels relying on the processor in the one of the display panels to process image data. This allows effective use of a single processor by several display panels. Optionally, there could be two or more master display device on the mounting board instead of just one as described for FIG. 13 and FIG. 13a.

Furthermore, some embodiments 100 described have a mounting board 101, wherein the mounting board 101 comprises a data bus for a first display panel 903 attached to the mounting board to access a processor in a second display panel 903a attached to the mounting board, wherein the processor in the second display panel processing image data for the display panel.

Furthermore, some embodiments 100 described have a display panel 903a for mounting to a mounting board 101, wherein the display panel relies on a processor in another display panel 903 mounted to the mounting board 101 to process image data.

Furthermore, some embodiments 100 described have a display panel 903 for mounting to a mounting board 101, wherein the display panel has a processor for processing image data for another display panel 903 mounted to the mounting board 101.

As the skilled man knows how to program the specific images of different formats and direct them to the appropriate or selected display panel 103 by conventional programming and wiring technology, such details are omitted here.

Variations of the invention, although not described in detail, are within the understanding of the skilled man.

For example, the skilled man understands that in different embodiments 100, the display panels 103 are able to receive image data in either digital or analogue forms, or both.

Furthermore, the skilled man understands that depending on the images selected to be shown in each display panel, the images in the display panels 103 can combine to form a single larger image or can be entirely unrelated images. The skilled man also understands that some of the images can be static while others are moving. In this way, the embodiments 100 allow room for creative display.

The skilled man also understands that the mounting board 101 can be designed and made such that the display panels 103 suitable for mounting onto the mounting board 101 can be of different sizes, from different manufacturers or show different images in different formats.

The skilled man also understands that the display panels is removably mounted by the user onto the mounting board 101 in some embodiments 100, and is fixedly mounted by the manufacturer based in some other embodiments 100.

The skilled man also understands that although a battery is disclosed in the display panels, which is chargeable by induction, it is possible to directly operate the display panels by induction power, without needing a re-chargeable a battery.

Furthermore, the skilled man understands that different features of the different embodiments 100 may be combined to vary the embodiments 100. For example, although not described above, the skilled man understands that the embodiment 100 of FIG. 15 can be modified such that either or both the master display panel and the secondary display panels can receive image data wirelessly. The skilled man also understands that it is possible to equip all the display panels and also the mounting board 101 with a processor each. The skilled man also understands that while images have been described so far, the display in any of the display panels a can also be textual.

1. A display assembly comprising:
a mounting board;
at least one attachment device on the mounting board;
at least one display panel mounted to the attachment device;
the mounting board capable of providing power to operate the at least one display panel.

2. A display assembly as claimed in claim 1 wherein the at least one display panel is removably mounted to the attachment device.

3. A display assembly as claimed in claim 1 wherein the at least one display panel is mounted to the attachment device such that the at least one display panel can be moved to change the angle of the at least one display panel to the mounting board.

4. A display assembly as claimed in claim 1, wherein the attachment device on the mounting board is movable.

5. A display assembly as claimed in claim 1, wherein the mounting board is capable of providing image data to the at least one display panel.

6. A display assembly as claimed in claim 1, wherein the mounting board capable of providing power to operate the at least one display panel by induction.

7. A display assembly as claimed in claim 1, wherein the display assembly comprises a plurality of display panels, at least one of the display panels relying on a processor in another one of the display panels to process image data for display.

8. A mounting board comprising:
an attachment device;
the attachment device for attaching to a display panel; and
power connection to operate the display panels.

9. A mounting board as claimed in claim 8, wherein the attachment device attaches to the display panel removably.

10. A mounting board as claimed in claim 8, wherein the attachment device attaches to the display panel such that the display panel is movable to change the angle of the display panel to the mounting board.

11. A mounting board as claimed in claim 8, wherein the position of attachment device on the mounting board is movable.

12. A mounting board as claimed in claim 8, wherein the mounting board is capable of providing image data the display panel.

13. A mounting board as claimed in claim 8, wherein the mounting board is capable of providing power to operate the display panel by induction.

14. A mounting board as claimed in claim 8, wherein the mounting board comprises a processor for processing image data for the display panel.

15. A mounting board as claimed in claim 8, wherein the mounting board comprises a data bus for a first display panel attached to the mounting board to access a processor in a second display panel attached to the mounting board, wherein the processor in the second display panel processing image data for the display panel.

16. A display panel for mounting to an attachment device of a mounting board, wherein the mounting board provides power to operate the display panel.

17. A display panel as claimed in claim 16, wherein the display panel is removable attached to the attachment device.

18. A display panel as claimed in claim 16, wherein the display panel is movably attached to the attachment device, such that the angle of the display panel to the mounting board is variable.

19. A display panel as claimed in claim 16, wherein the display panel relies on a processor in the mounting board to process image data.

20. A display panel as claimed in claim 16, wherein the display panel relies on a processor in another display panel mounted to the mounting board to process image data.

21. A display assembly comprising:
a mounting board;
two or more display panels mounted to the mounting board; wherein one of the display panels comprises a processor; and the other display panels relying on the processor in the one of the display panels to process image data.
